(19) United States
(12) Patent Application Publication
(10) Pub. No.: US 2024/0072199 A1
(43) Pub. Date: Feb. 29, 2024

(54) SEMICONDUCTOR STRUCTURES AND MANUFACTURING METHODS THEREOF

(71) Applicant: ENKRIS SEMICONDUCTOR, INC., Suzhou (CN)

(72) Inventor: Kai Cheng, Suzhou (CN)

(73) Assignee: ENKRIS SEMICONDUCTOR, INC., Suzhou (CN)

(21) Appl. No.: 18/338,975

(22) Filed: Jun. 21, 2023

(30) Foreign Application Priority Data
Aug. 25, 2022 (CN) 202211028466.3

(51) Int. Cl. H01L 33/00; H01L 33/20

(52) U.S. Cl. CPC H01L 33/007; H01L 33/20

(57) ABSTRACT

The present disclosure provides a semiconductor structure, including: a substrate, a first-type mask layer, a second-type mask layer, and an epitaxial layer; where the first-type mask layer includes a first mask multilayer, the first mask multilayer includes a first mask layer and a second mask layer, the first mask layer includes a first window, the second mask layer includes a second window communicating with the first window, the second window and the first window constitute a first-type window, and a cross-section of the second window is larger than that of the first window; the second-type mask layer is located on a side of the first-type mask layer away from the base; the second-type mask layer includes a second-type window communicating with the first-type window, and a cross-section of the second-type window is smaller than that of the second window.

### CROSS REFERENCE TO RELATED APPLICATIONS

This application claims priority to Chinese Patent Application No. 2022110284663, filed on Aug. 25, 2022, the entire content of which is incorporated herein by reference.

### TECHNICAL FIELD

The present disclosure relates to the field of semiconductor technology, in particular to semiconductor structures and manufacturing methods thereof.

### BACKGROUND

Gallium nitride (GaN) is the third generation of new semiconductor materials after the first and second generation of semiconductor materials such as Si and GaAs. As a wide band gap semiconductor material, GaN has many advantages, such as high saturation drift speed, high breakdown voltage, excellent carrier transport performance, the ability to form AlGaN, InGaN ternary alloys and AlInGaN quaternary alloys, and easy manufacturing of GaN-based PN junctions. In view of this, GaN-based materials and semiconductor devices have been extensively and deeply studied in recent years, and the growth of GaN-based materials by MOCVD (metal-organic chemical vapor deposition) technology is becoming increasingly mature. In the research of semiconductor devices, the research of optoelectronic devices such as GaN-based LED (light-emitting diode) and LD (laser diode) and microelectronic devices such as GaN-based HEMT (High Electron Mobility Transition) has achieved remarkable achievements and great development.

With the gradual deepening of the application of GaN-based materials in power devices and display devices, the demand of terminal products for dislocation density of GaN-based materials has been further improved. According to the traditional method, the dislocation density of GaN-based materials grown by using general MOCVD epitaxial equipment on the general GaN-based epitaxial base (such as the aluminum oxide (Al₂O₃) base) is about 1-3E8/cm³. In order to manufacture GaN-based power devices with higher voltage resistance and GaN-based LEDs with longer wavelength, the dislocation density of GaN-based materials needs to be further reduced.

In view of this, it is necessary to provide a new semiconductor structure and a manufacturing method thereof to meet the above requirements.

### SUMMARY

The present disclosure aims to provide a semiconductor structure and a manufacturing method thereof to reduce the dislocation density of GaN-based materials.

In order to achieve the above purpose, a first aspect of the present disclosure provides a semiconductor structure, including:

a base;

a first-type mask layer on the base, where the first-type mask layer includes a first-type window, the first-type mask layer includes a first mask multilayer, the first mask multilayer includes a first mask layer close to the base and a second mask layer far from the base, the first mask layer includes a first window, the second mask layer includes a second window, the second window connects to the first window, the first window and the second window constitute the first-type window, and an area of a cross-section of the second window is larger than an area of a cross-section of the first window, where the cross-section refers to a section parallel to a plane of the base; and

a second-type mask layer on a side of the first-type mask layer far from the base, where the second-type mask layer includes a second-type window, the second-type window connects to the first-type window, and an area of a cross-section of the second-type window is smaller than an area of a cross-section of the second window.

Optionally, a material of the first mask layer is the same as a material of the second-type mask layer and is different from a material of the second mask layer.

Optionally, the semiconductor structure further includes a third-type mask layer between the first-type mask layer and the base, where the third-type mask layer includes a third-type window that exposes the base, the third-type window connects to the first-type window, and an area of a cross-section of the third-type window is larger than the area of the cross-section of the first window.

Optionally, the first-type mask layer further includes a second mask multilayer, . . . , a N-th mask multilayer, N is an integer greater than or equal to 2, a M-th mask multilayer includes a (2M-1)-th mask layer close to the base and a (2M)-th mask layer far from the base, M is any integer greater than or equal to 2 and less than or equal to N, the (2M-1)-th mask layer includes a (2M-1)-th window, the (2M)-th mask layer includes a (2M)-th window, the (2M)-th window connects to the (2M-1)-th window, the (2M)-th window and the (2M-1)-th window constitute at least part of the first-type window, an area of a cross-section of the (2M)-th window is larger than an area of a cross-section of the (2M-1)-th window, and the area of the cross-section of the second-type window is smaller than an area of a cross-section of a (2N)-th window.

Optionally, the area of the cross-section of the (2M-1)-th window is smaller than an area of a cross-section of a (2M-2)-th window.

Optionally, in the first-type mask layer, all even-numbered mask layers have the same refractive index, all odd-numbered mask layers have the same refractive index, and the refractive index of the even-numbered mask layers is different from the refractive index of the odd-numbered mask layers to form a Bragg reflector.

Optionally, the semiconductor structure further includes an epitaxial layer in the first-type window and the second-type window.

Optionally, the semiconductor structure further includes a light-emitting structure on a side of the epitaxial layer far from the base.

Optionally, the light-emitting structure includes an active layer on a side of the epitaxial layer far from the base.

Optionally, the semiconductor structure comprises a plurality of the first-type windows and a plurality of the second-type windows, adjacent multiple second-type windows constitute a group, and an area of a cross-section of each second-type window in the same group is different, or a spacing between each adjacent pairs of second-type windows in the same group is different.

Optionally, the semiconductor structure comprises a plurality of the first-type windows and a plurality of the second-type windows, and epitaxial layers corresponding to the plurality of the first-type windows and the plurality of the second-type windows coalesce into a plane.

A second aspect of the present disclosure provides a manufacturing method of a semiconductor structure, including:

providing a base; sequentially forming a first-type mask layer and a second-type mask layer on the base; where the first-type mask layer includes a first-type window, the first-type mask layer includes a first mask multilayer, the first mask multilayer includes a first mask layer close to the base and a second mask layer far from the base, the first mask layer includes a first window, the second mask layer includes a second window, the second window connects to the first window, the first window and the second window constitute the first-type window, and an area of a cross-section of the second window is larger than an area of a cross-section of the first window, where the cross-section refers to a section parallel to a plane of the base, and the second-type mask layer includes a second-type window, the second-type window connects to the first-type window, and an area of a cross-section of the second-type window is smaller than the area of the cross-section of the second window.

Optionally, the manufacturing method further includes: performing an epitaxial growth process on the base, by using the first-type mask layer and the second-type mask layer as masks, to form an epitaxial layer, where the epitaxial layer fills up the first-type window and the second-type window.

Optionally, a material of the first mask layer is the same as a material of the second-type mask layer and is different from a material of the second mask layer; and

sequentially forming the first-type mask layer and the second-type mask layer on the base includes:

sequentially forming a first-type mask material layer and a second-type mask material layer on the base, where the first-type mask material layer includes a first mask material multilayer, and the first mask material multilayer includes a first mask material layer close to the base and a second mask material layer far from the base;

etching the second-type mask material layer and the first-type mask material layer to form an opening that exposes the base; and

laterally etching the second mask material layer through the opening to form a second window, where a part of the opening located in the first mask material layer forms a first window, and a part of the opening located in the second-type mask material layer forms a second-type window.

Optionally, before forming the first-type mask layer on the base, the manufacturing method further includes: forming a third-type mask layer on the base, where the third-type mask layer includes a third-type window that exposes the base, the third-type window connects to the first-type window, and an area of a cross-section of the third-type window is larger than the area of the cross-section of the first window.

Optionally, a material of the first mask layer is the same as a material of the second-type mask layer, a material of the second mask layer is the same as a material of the third-type mask layer and is different from a material of the first mask layer; and

sequentially forming the first-type mask layer and the second-type mask layer on the base includes:

sequentially forming a third-type mask material layer, a first-type mask material layer and a second-type mask material layer on the base, where the first-type mask material layer includes a first mask material layer close to the base and a second mask material layer far from the base;

etching the second-type mask material layer, the first-type mask material layer and the third-type mask material layer to form an opening that exposes the base; and

laterally etching the second mask material layer through the opening to form a second window, and laterally etching the third-type mask material layer through the opening to form a third-type window, where a part of the opening located in the first mask material layer forms a first window, and a part of the opening located in the second-type mask material layer forms a second-type window.

Compared with the prior art, the present disclosure has the following beneficial effects:

A semiconductor structure including a first-type mask layer and a second-type mask layer is used as a base for epitaxial growth, where the first-type mask layer includes a first-type window, the first-type window includes a first window close to the base and a second window far from the base, an area of a cross-section of the second window is larger than an area of a cross-section of the first window, and the second-type mask layer includes a second-type window, an area of a cross-section of the second-type window is smaller than an area of a cross-section of the second window. The first window→the second window→the second-type window corresponds to small size→large size→small size. During the epitaxial growing process from a “small size” region to a “large size” region, most of the dislocations are bent horizontally with the lateral epitaxial growth and then stopped. The unstopped dislocations are further stopped at the bottom wall of the second-type mask layer during the epitaxially growing process from a “large size” region to a “small size” region, thus reducing the dislocation density in epitaxial growth.

### BRIEF DESCRIPTION OF DRAWINGS

FIG. 1 is a cross-sectional structure diagram of a semiconductor structure according to a first embodiment of the present disclosure.

FIG. 2 is a cross-sectional structure diagram of a base, a first-type mask layer and a second-type mask layer in FIG. 1.

FIG. 3 is a flowchart of a manufacturing method of the semiconductor structure in FIG. 1.

FIG. 4 and FIG. 5 are schematic diagrams of intermediate structures corresponding to processes in FIG. 3.

FIG. 6 is a cross-sectional structure diagram of a semiconductor structure according to a second embodiment of the present disclosure.

FIG. 7 is a cross-sectional structure diagram of a semiconductor structure according to a third embodiment of the present disclosure.

FIG. 8 is a cross-sectional structure diagram of a base, a first-type mask layer and a second-type mask layer in FIG. 7.

FIG. 9 and FIG. 10 are schematic diagrams of intermediate structures corresponding to a manufacturing method of the semiconductor structure according to the third embodiment of the present disclosure.

FIG. 11 is a cross-sectional structure diagram of a semiconductor structure according to a fourth embodiment of the present disclosure.

FIG. 12 is a cross-sectional structure diagram of a base, a first-type mask layer and a second-type mask layer in FIG. 11.

FIG. 13 and FIG. 14 are schematic diagrams of intermediate structures corresponding to a manufacturing method of the semiconductor structure according to the fourth embodiment of the present disclosure.

FIG. 15(a) and FIG. 15(b) are cross-sectional structure diagrams of two semiconductor structures according to a fifth embodiment of the present disclosure.

FIG. 16 is a cross-sectional structure diagram of a semiconductor structure according to a sixth embodiment of the present disclosure.

FIG. 17 is a cross-sectional structure diagram of a base, a first-type mask layer and a second-type mask layer in FIG. 16.

FIG. 18 is a cross-sectional structure diagram of a semiconductor structure according to a seventh embodiment of the present disclosure.

FIG. 19 is a schematic top view of a base, a first-type mask layer and a second-type mask layer in FIG. 18.

FIG. 20 is a cross-sectional structure diagram of a semiconductor structure according to an eighth embodiment of the present disclosure.

For the convenience of understanding the present disclosure, all reference numerals appearing in the present disclosure are listed below.

| | |
|---|---|
| semiconductor structures 1, 2, 3, 4, 5, 6, 7 | base 10 |
| and 8 | |
| semiconductor substrate 100 | transition layer 101 |
| first-type mask layer 11 | first-type window 110 |
| first mask multilayer 111 | first mask layer 121 |
| second mask layer 122 | first window 121a |
| second window 122a | second-type mask layer 12 |
| second-type window 120 | epitaxial layer 21 |
| first-type mask material layer 11′ | first mask material |
| | multilayer 111′ |
| first mask material layer 121′ | second mask material layer |
| | 122′ |
| N-th mask multilayer 11n | (2N-1)-th mask layer |
| | 12(2n-1) |
| (2N)-th mask layer 12(2n) | (2N-1)-th window 12(2n- |
| | 1)a |
| (2N)-th window 12(2n)a | N-th mask material |
| | multilayer 11n′ |
| (2N)-th mask material layer 12(2n)′ | (2N-1)-th mask material |
| | layer 12(2n-1)′ |
| M-th mask multilayer 11m | (2M-1)-th mask layer |
| | 12(2m -1) |
| (2M)-th mask layer 12(2m) | (2M-1)-th window 12(2m- |
| | 1)a |
| (2M)-th window 12(2m)a | (2M)-th mask material |
| | layer 12(2m)′ |
| (2M-1)-th mask material layer 12(2m -1)′ | second-type mask material |
| | layer 12′ |
| opening 10a | third-type mask layer 13 |
| third-type window 130 | third-type mask material |
| | layer 13′ |
| epitaxial layer 21 | emitting structure 22 |
| active layer 221 | area of cross-section D |

### DETAILED DESCRIPTION

In order to make the above-mentioned objects, features and advantages of the present disclosure more obvious and understandable, embodiments of the present disclosure will be described in detail below with reference to the accompanying drawings.

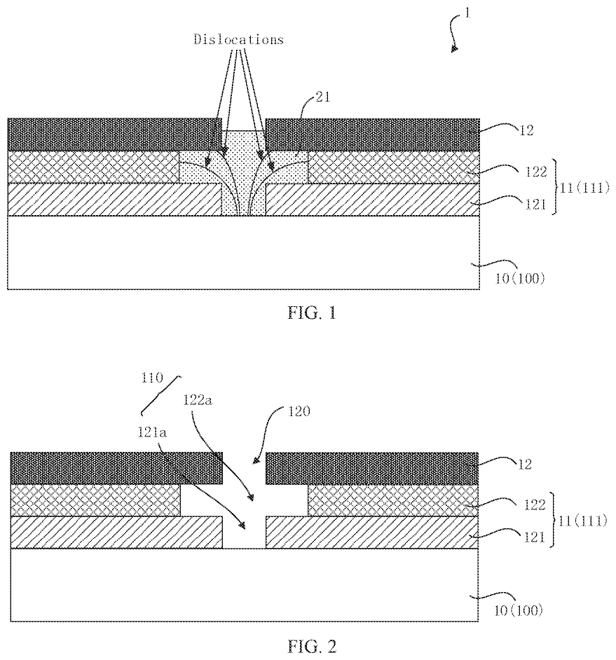

FIG. 1 is a cross-sectional structure diagram of a semiconductor structure according to a first embodiment of the present disclosure. FIG. 2 is a cross-sectional structure diagram of a base, a first-type mask layer and a second-type mask layer in FIG. 1.

Referring to FIG. 1 and FIG. 2, the semiconductor structure 1 includes:

a base 10;

a first-type mask layer 11 located on the base 10, where the first-type mask layer 11 includes a first-type window 110, the first-type of mask layer 11 includes a first mask multilayer 111, the first mask multilayer 111 includes a first mask layer 121 close to the base 10 and a second mask layer 122 far from the base 10, the first mask layer 121 includes a first window 121a, the second mask layer 122 includes a second window 122a, the second window 122a connects to (e.g., communicates with) the first window 121a, the second window 122a and the first window 121a constitute a first-type window 110, and an area of a cross-section of the second window 122a is larger than an area of a cross-section of the first window 121a, where the cross-sections are sections parallel to a plane of the base 10; and

a second-type mask layer 12, located on a side of the first-type mask layer 11 far from the base 10, where the second-type mask layer 12 includes a second-type window 120, the second-type window 120 communicates with the first-type window 110, and an area of a cross-section of the second-type window 120 is smaller than an area of a cross-section of the second window 122a.

Referring to FIG. 1, in this embodiment, the base 10 is a multi-layer structure. The base 10 includes, for example, a semiconductor substrate 100 and a nucleation layer (not shown) on the semiconductor substrate 100. A material of the semiconductor substrate 100 may include at least one of sapphire, silicon carbide and monocrystalline silicon, and a material of the nucleation layer may include AN.

In other embodiments, the base 10 may include a single layer structure, for example, the base 10 includes a semiconductor substrate 100. A material of the semiconductor substrate 100 may include silicon carbide or gallium nitride.

In the first mask multilayer 111, a material of the first mask layer 121 is different from a material of the second mask layer 122. The material of the first mask layer 121 can be silicon dioxide, and the material of the second mask layer 122 is silicon nitride. A material of the second-type mask layer 12 is different from a material of the second mask layer 122, and the material of the second-type mask layer 12 and the material of the first mask layer 121 can be the same.

In this embodiment, the semiconductor structure 1 includes one first-type window 110 and one second-type window 120. Therefore, the semiconductor structure 1 has one first window 121a and one second window 122a.

In this embodiment, the vertical cross-sections of the first window 121a, the second window 122a and the second-type window 120 are rectangular. The vertical cross-section here refers to a section vertical to the plane of the base 10. In other embodiments, the vertical cross-sections of the first window 121a, the second window 122a, and the second-type window 120 may also have other shapes.

The cross-sections of the first window 121a, the second window 122a and the second-type window 120 can be rectangular, triangular, hexagonal, circular and other shapes. The cross-sections here refer to sections parallel to the plane of the base 10, that is, the cross-sections are parallel to the plane of the base 10.

In this embodiment, the semiconductor structure 1 may further includes an epitaxial layer 21 located in the first-type window 110 and the second-type window 120. As shown in FIG. 1, the material of epitaxial layer 21 can be GaN-based material, such as at least one of GaN, AlGaN, InGaN and AlInGaN, which is not limited in this embodiment.

The dislocations of GaN-based materials are mainly linear dislocations in the crystal orientation of [0001], that is, linear dislocations extending along the thickness direction. It should be noted that, as shown in FIG. 1, the dislocation is only used to indicate the dislocation direction and does not represent the real dislocation in the semiconductor structure, which cannot be used to limit the semiconductor structure provided by this embodiment.

In this embodiment, referring to FIG. 2, in the first mask multilayer 111, the first-type window 110 includes the first window 121a close to the base 10 and the second window 122a far from the base 10. An area of a cross-section of the second window 122a is larger than an area of a cross-section of the first window 121a, that is, the first window 121a→the second window 122a corresponds to small size→large size. This makes: as shown in FIG. 1, when the semiconductor structure is used for epitaxial production of semiconductor devices, during the process of epitaxial growth of the epitaxial layer 21 from a small size region to a large size region, most of the dislocations are bent horizontally and stopped with the lateral epitaxial growth, thus reducing the dislocation density of the epitaxial layer 21.

As shown in FIG. 2, an area of a cross-section of the second-type window 120 is smaller than an area of a cross-section of the second window 122a, that is, the second window 122a→the second-type window 120 corresponds to large size→small size. This makes: as shown in FIG. 1, the unstopped dislocations in the epitaxial layer 21 are further stopped on the bottom wall of the second-type mask layer 12 during the growth process from a large size region to a small size region, thus further reducing the dislocation density of the epitaxial layer 21. It should be noted that the bottom wall of the second-type mask layer 12 here refers to the surface of the second-type mask layer 12 close to the base 10.

In other embodiments, the epitaxial layer 21 can also be located on a side of the second-type mask layer 12 far from the base 10.

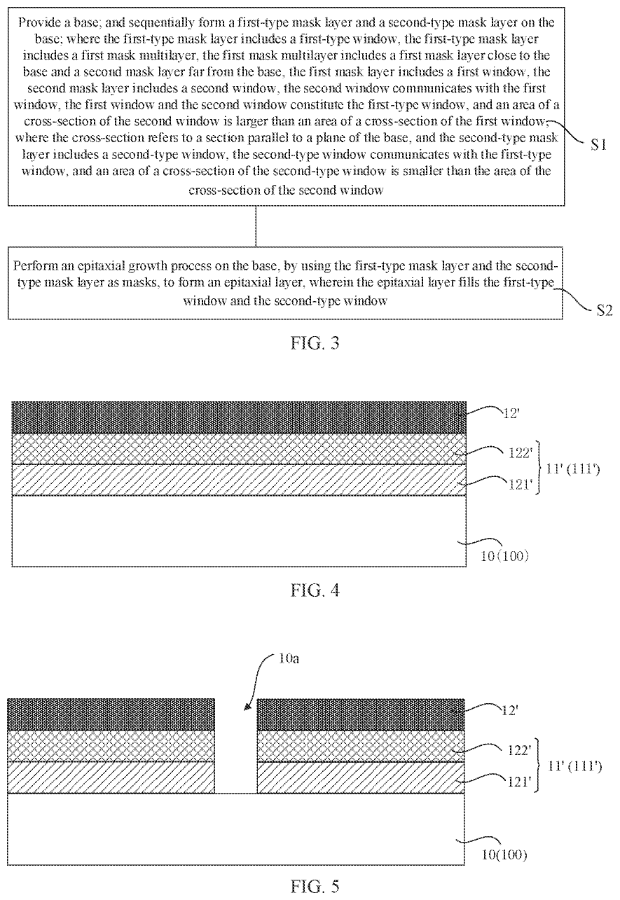

The first embodiment of the present disclosure further provides a manufacturing method of the semiconductor structure in FIG. 1. FIG. 3 is a flowchart of the manufacturing method. FIG. 4 and FIG. 5 are schematic diagrams of intermediate structures corresponding to processes in FIG. 3.

First, referring to step S1 in FIG. 3 and as shown in FIG. 2, the base 10 is provided; the first-type mask layer 11 and the second-type mask layer 12 are sequentially formed on the base 10; where the first-type mask layer 11 includes a first-type window 110, the first-type mask layer 11 includes a first mask multilayer 111, the first mask multilayer 111 includes a first mask layer 121 close to the base 10 and a second mask layer 122 far from the base 10, the first mask layer 121 includes a first window 121a, the second mask layer 122 includes a second window 122a, the second window 122a communicates with the first window 121a, the second window 122a and the first window 121a constitute the first-type window 110, and an area of a cross-section of the second window 122a is larger than an area of a cross-section of the first window 121a, where the cross-sections refers to sections parallel to the plane of base 10, and the second-type mask layer 12 includes a second-type window 120, the second-type window 120 communicates with the first-type window 110, and an area of a cross-section of the second-type window 120 is smaller than an area of a cross-section of the second window 122a.

In this embodiment, step S1 may include steps S11 to S13.

In step S11, as shown in FIG. 4, the first-type mask material layer 11′ and the second-type mask material layer 12′ are sequentially formed on the base 10, the first-type mask material layer 11′ includes a first mask material multilayer 11F, the first mask material multilayer 11F includes a first mask material layer 121′ close to the base 10 and a second mask material layer 122′ far from the base 10. Optionally, a material of the first mask material layer 121′ is the same as a material of the second-type mask material layer 12′ and is different from a material of the second mask material layer 122′.

Referring to FIG. 4, the base 10 is a multi-layer structure. The base 10 includes, for example, a semiconductor substrate 100 and a nucleation layer (not shown) on the semiconductor substrate 100. A material of the semiconductor substrate 100 may include at least one of sapphire, silicon carbide and monocrystalline silicon, and a material of the nucleation layer may include AN.

In other embodiments, the base 10 may include a single layer structure, for example, the base 10 includes a semiconductor substrate 100. A material of the semiconductor substrate 100 may include silicon carbide or gallium nitride.

In this embodiment, the materials of the first mask material layer 121′ and the second-type mask material layer 12′ can include silicon dioxide, and the material of the second mask material layer 122′ includes silicon nitride, which can be formed by physical vapor deposition or chemical vapor deposition. In other embodiments, the materials of the first mask material layer 121′ and the second-type mask material layer 12′ can be other materials different from the material of the second mask material layer 122′, and/or the materials of the first mask material layer 121′ and the second-type mask material layer 12′ are different.

In step S12, as shown in FIG. 5, the second-type mask material layer 12′ and the first-type mask material layer 11′ are etched to form an opening 10a exposing the base 10. Optionally, dry etching can be used for etching in this step.

In step S13, as shown in FIG. 5 and FIG. 2, the second window 122a is formed by lateral etching for the second mask material layer 122′ through the opening 10a. The part of the opening 10a located in the first mask material layer 121′ forms the first window 121a, and the part of the opening 10a located in the second-type mask material layer 12′ forms the second-type window 120. The second mask material layer 122′ can be laterally etched using a hot phosphoric acid solution, and an area of a cross-section of the second window 122a can be controlled by the etching time. After lateral etching, the first-type mask material layer 11′ forms the first-type mask layer 11, the first mask material layer 121′ forms the first mask layer 121, the second mask material layer 122′ forms the second mask layer 122, and the second-type mask material layer 12′ forms the second-type mask layer 12.

Optionally, the materials of the first mask material layer 121′ and the second-type mask material layer 12′ can include silicon dioxide with high aluminum content, and the material of the second mask material layer 122′ is silicon dioxide with low aluminum content. An etching speed for the second mask material layer 122′ is faster than an etching speed for the first mask material layer 121′ and the second-type mask material layer 12′, finally to form the first-type window 110 and the second-type window 120 as shown in FIG. 2.

In other embodiments, the first-type window 110 and the second-type window 120 can also be implemented by removing an occupying layer. Specifically, step S1 may include steps S11′ to S16′.

In step S11′, a first occupying material layer is formed on the base 10, where the first occupying material layer is patterned by an etching process to form the first occupying layer, and the position, shape and size of the first occupying layer correspond to the position, shape and size of the first window 121a.

In step S12′, a first mask material layer 121′ is formed on the first occupying layer and the base 10; and the first mask material layer 121′ is polished until the first occupying layer is exposed.

In step S13′, a second occupying material layer is formed on the first occupying layer and the first mask material layer 121′, where the second occupying material layer is patterned by an etching process to form a second occupying layer, and the position, shape and size of the second occupying layer correspond to the position, shape and size of the second window 122a. A material of the second occupying material layer can be the same as a material of the first occupying material layer, for example, the material of the second occupying material layer and the material of the first occupying material layer can be silicon nitride.

In step S14′, a second mask material layer 122′ is formed on the second occupying layer and the first mask material layer 121′; and the second mask material layer 122′ is polished until the second occupying layer is exposed. A material of the second mask material layer 122′ can be the same as a material of the first mask material layer 121′, and is different from materials of the second occupying material lay and the first occupying material layer. The materials of the second mask material layer 122′ and the first mask material layer 121′ can be silicon dioxide.

In step S15′, a second-type mask material 12′ layer is formed on the second occupation layer and the second mask material layer 122′; and the second-type mask material layer 12′ is patterned by an etching process to form a second-type window 120. A material of the second-type mask material layer 12′ and a material of the second mask material layer 122′ can be the same as a material of the first mask material layer 121′, and different from materials of the second occupying material lay and the first occupying material layer.

In step S16′, the second occupying material layer is etched through the second-type window 120 to form a second window 122a, and the first occupying material layer is etched through the second-type window 120 to form a first window 121a. Etching for the first occupying material layer and the second occupying material layer can be performed with hot phosphoric acid solution. The first mask material layer 121′ forms the first mask layer 121, the second mask material layer 122′ forms the second mask layer 122, and the second-type mask material layer 12′ forms the second-type mask layer 12.

Next, referring to step S2 in FIG. 3 and as shown in FIG. 1, the manufacturing method further includes: performing an epitaxial growth process on the base 10 to form the epitaxial layer 21, by taking the first-type mask layer 11 and the second-type mask layer 12 as masks, where the epitaxial layer 21 fills the first-type window 110 and the second-type window 120.

The formation process of the epitaxial layer 21 may include: atomic layer deposition (ALD), chemical vapor deposition (CVD), molecular beam epitaxy (MBE), plasma enhanced chemical vapor deposition (PECVD), low pressure chemical vapor deposition (LPCVD), metal-organic chemical vapor deposition (MOCVD), or a combination thereof.

When the base 10 is a multilayer structure, for example, including the semiconductor substrate 100 and the nucleating layer on the semiconductor substrate 100, the epitaxial growing of the epitaxial layer 21 on the base 10 is heteroepitaxial. The base 10 is a single-layer structure, for example, when the semiconductor substrate 100 is made of silicon carbide or gallium nitride, the epitaxial layer 21 is homoepitaxial.

A material of epitaxial layer 21 can include GaN-based material, such as at least one of GaN, AlGaN, InGaN or AlInGaN. Dislocations in GaN-based materials mainly extend along the thickness direction. As shown in FIG. 1, the epitaxial growth process of the epitaxial layer 21 GaN-based material from the first window 121a to the second window 122a is from a small size region to a large size region. When semiconductor structures are used for epitaxial production of semiconductor devices, during the epitaxially growing process from a small size region to a large size region, most of the dislocations are bent horizontally and stopped with the lateral epitaxial growth, thus reducing the dislocation density of the epitaxial layer 21. As shown in FIG. 1, the epitaxial growth process of the epitaxial layer 21 GaN-based material from the second window 122a to the second-type window 120 is from a large size region to a small size region. During the epitaxially growing process from a large size region to a small size region, the unstopped dislocations in the epitaxial layer 21 GaN-based material can be further stopped at the bottom wall of the second-type mask layer 12, thus further reducing the dislocation density of the epitaxial layer 21.

In other embodiments, the epitaxial layer 21 can fill up the second-type window 120 by extending the epitaxial growth process time.

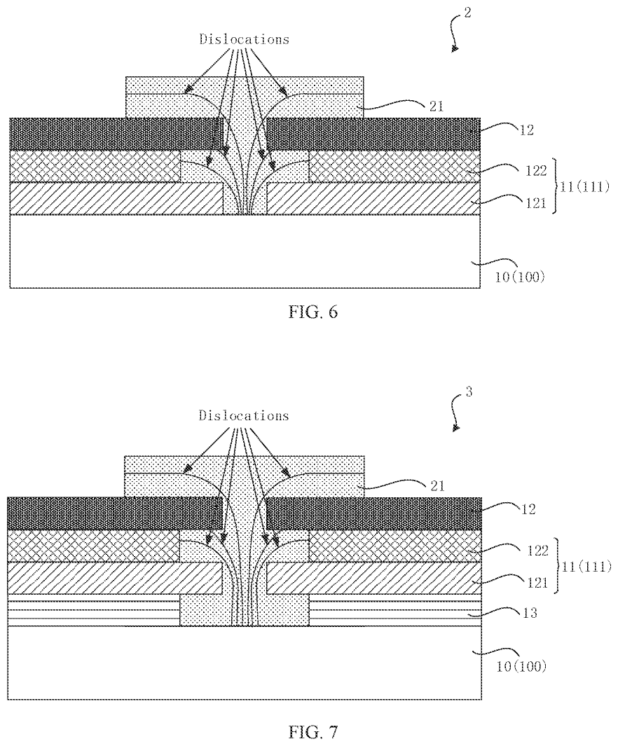

FIG. 6 is a cross-sectional structure diagram of a semiconductor structure according to a second embodiment of the present disclosure.

As shown in FIG. 6, a semiconductor structure 2 and a manufacturing method thereof according to the second embodiment is different from the semiconductor structure 1 and the manufacturing method thereof according to the first embodiment in that the epitaxial layer 21 fills up the first-type window 110 and the second-type window 120, and is located on a side of the second-type mask layer 12 far from the base 10.

As shown in FIG. 2, the second-type window 120→the side of the second-type mask layer 12 far from the base 10 corresponds to small size→large size. This makes: as shown in FIG. 6, during the epitaxially growing of the epitaxial layer 21 from a small size region to a large size region, the unstopped dislocations in the epitaxial layer 21 can be bent horizontally and stopped with the lateral epitaxial growth, thus further reducing the dislocation density of the epitaxial layer 21.

In addition to the above differences, other structures and process steps of the semiconductor structure 2 according to the second embodiment can refer to the corresponding structures and process steps of the semiconductor structure 1 corresponding to the first embodiment.

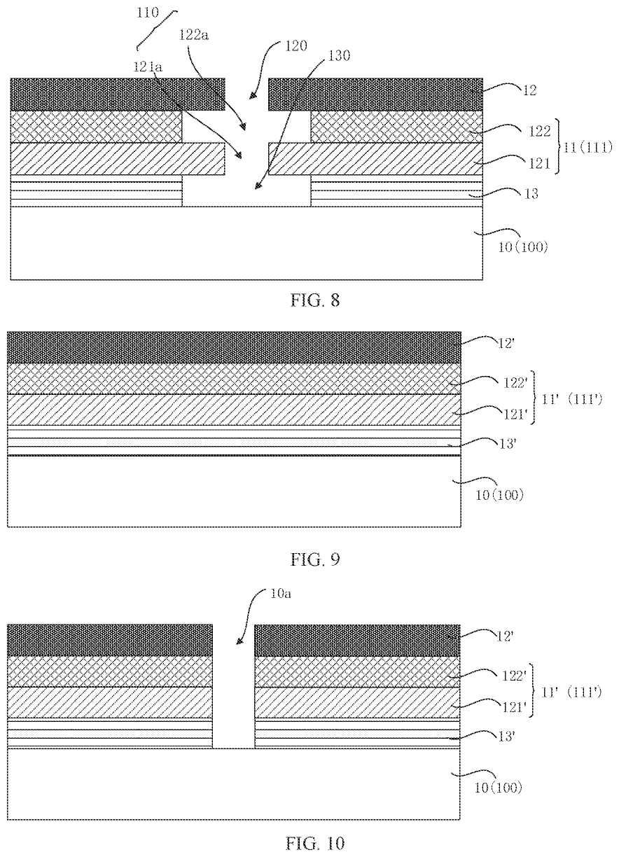

FIG. 7 is a cross-sectional structure diagram of a semiconductor structure according to a third embodiment of the present disclosure. FIG. 8 is a cross-sectional structure diagram of a base, a first-type mask layer and a second-type mask layer in FIG. 7.

As shown in FIG. 7 and FIG. 8, a semiconductor structure 3 according to the third embodiment is different from the semiconductor structure 1 and 2 according to the first and second embodiments in that a third-type mask layer 13 is provided between the first-type mask layer 11 and the base 10, where the third-type mask layer 13 includes a third-type window 130 that exposes the base 10, the third-type window 130 communicates with the first-type window 110, and an area of a cross-section of the third-type window 130 is larger than an area of a cross-section of the first window 121a.

As shown in FIG. 8, the third-type window 130→the first window 121a corresponds to large size→small size. The advantages are: on the one hand, the nucleation area of the epitaxial layer 21 on the base 10 is large, such that the epitaxial layer 21 is easy to grow. On the other hand, during the epitaxially growing process of epitaxial layer 21 from a large size region to a small size region, some dislocations in epitaxial layer 21 can be stopped at the bottom wall of first mask layer 121, thereby reducing the dislocation density of epitaxial layer 21.

In addition to the above differences, other structures of the semiconductor structure 3 according to the third embodiment can refer to the corresponding structures of the semiconductor structures 1 and 2 corresponding to the first and second embodiments.

FIG. 9 and FIG. 10 are schematic diagrams of intermediate structures corresponding to a manufacturing method of the semiconductor structure according to the third embodiment of the present disclosure.

Accordingly, a manufacturing method of the semiconductor structure 3 according to the third embodiment is different from the manufacturing method of the semiconductor structures 1 and 2 according to the first and second embodiments in that step S1 includes steps S11″ to S13″.

In step S11″, as shown in FIG. 9, the third-type mask material layer 13′, the first-type mask material layer 11′ and the second-type mask material layer 12′ are sequentially formed on the base 10, where the first-type mask material layer 11′ includes the first mask material layer 121′ close to the base 10 and the second mask material layer 122′ far from the base 10.

Materials of the third-type mask material layer 13′ and the second mask material layer 122′ can include silicon nitride, and materials of the first mask material layer 121′ and the second-type mask material layer 12′ can include silicon dioxide, which can be formed by physical vapor deposition or chemical vapor deposition.

In step S12″, as shown in FIG. 10, the second-type mask material layer 12′, the first-type mask material layer 11′ and the third-type mask material layer 13′ are etched to form an opening 10a exposing the base 10. Dry etching can be used for etching in this step.

In step S13″, as shown in FIG. 10 and FIG. 8, the second window 122a is formed by lateral etching of the second mask material layer 122′ through the opening 10a, the third-type window 130 is formed by the lateral etching of the third-type mask material layer 13′, the part of the opening 10a located in the first mask material layer 121′ forms the first window 121a, and the part of the opening 10a located in the second-type mask material layer 12′ forms the second-type window 120. The second mask material layer 122′ and the third-type mask material layer 13′ can be etched laterally by hot phosphoric acid solution, and an area of a cross-section of the second window 122a and an area of a cross-section of the third-type window 130 can be controlled by the etching time.

In other embodiments, the third-type window 130, the second-type window 120 and the first-type window 110 can also be achieved by removing an occupying layer.

In addition to the above differences, other steps of the manufacturing method of the semiconductor structure 3 according to the third embodiment can refer to the corresponding steps of the manufacturing methods of the semiconductor structures 1 and 2 according to the first and second embodiments.

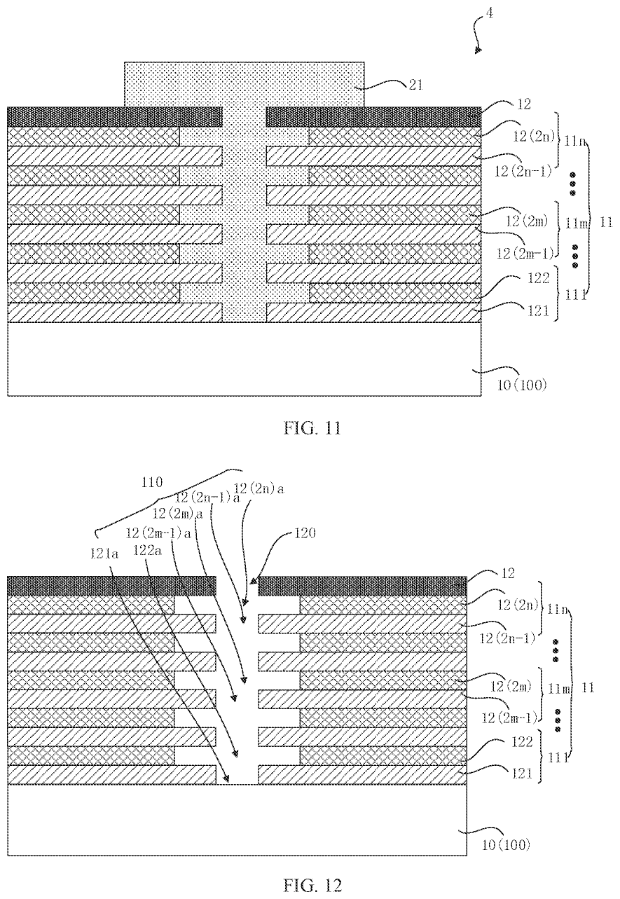

FIG. 11 is a cross-sectional structure diagram of a semiconductor structure according to a fourth embodiment of the present disclosure. FIG. 12 is a cross-sectional structure diagram of a base, a first-type mask layer and a second-type mask layer in FIG. 11.

Referring to FIG. 11 and FIG. 12, a semiconductor structure 4 according to the fourth embodiment is different from the semiconductor structure 3 according to the first to third embodiments in that the first-type mask layer 11 further includes a second mask multilayer, . . . , the N-th mask multilayer 11n, N is an integer greater than or equal to 2, a M-th mask multilayer 11m includes a (2M-1)-th mask layer 12(2m-1) close to the base 10 and a (2M)-th mask layer 12(2m) far from the base 10, M is any integer greater than or equal to 2 and less than or equal to N, the (2M-1)-th mask layer 12(2m-1) includes a (2M-1)-th window 12(2m-1)a, the (2M)-th mask layer 12(2m) includes a (2M)-th window 12(2m)a, the (2M)-th window 12(2m) communicates with the (2M-1)-th window 12(2m-1), the (2M)-th window 12(2m) and the (2M−1)-th window 12(2m-1) constitute at least part of the first-type window 110, an area of a cross-section of the (2M)-th window 12(2m)a is larger than an area of a cross-section of the (2M-1)-th window 12(2m-1)a, and the area of the cross-section of the second-type window 120 is smaller than an area of a cross-section of the (2N)-th window 12(2n)a.

In this embodiment, the first window 121a in the first mask layer 121, the second window 122a in the second mask layer 122, . . . , the (2M-1)-th window 12(2m-1)a in the (2M−1)-th mask layer 12(2m-1), the (2M)-th window 12(2m)a in the (2M)-th mask layer 12(2m), . . . , the (2N−1)-th window 12(2n-1)a in the (2N−1)-th mask layer 12(2n-1), and the (2N)-th window 12(2n)a in the (2N)-th mask layer 12(2n) jointly constitute the first-type window 110.

In this embodiment, as shown in FIG. 12, In the M-th mask multilayer 11m, an area of a cross-section of the (2M)-th window 12(2m)a is greater than an area of a cross-section of the (2M-1)-th window 12(2m-1)a, that is, the area of the cross-section of the (2M-1)-th window 12(2m-1)a→the (2M)-th window 12(2m)a corresponds to small size→large size. This makes: as shown in FIG. 11, when the epitaxial layer 21 grows epitaxially in the first-type window 110, N times of epitaxial growth processes of a small size region to a large size region are implemented. Because each epitaxial growth process of a small size region to a large size region can cause dislocations to bend horizontally and stop with the lateral epitaxial growth, the dislocation density of the epitaxial layer 21 is lowered for N times.

In this embodiment, referring to FIG. 12, further, an area of a cross-section of the (2M−1)-th window 12(2m-1)a in the M-th mask multilayer 11m is smaller than an area of a cross-section of the (2M-2)-th window in the (M-1)-th mask multilayer, in other words, the (2M-2)-th window→the (2M-1)-th window 12(2m-1)a corresponds to large size→small size. The advantage is that during the epitaxially growing of the epitaxial layer 21 from a large size region to a small size region, some dislocations in the epitaxial layer 21 can stop at the bottom wall of the (2M-1)-th mask layer 12(2m-1), thus reducing the dislocation density of the epitaxial layer 21.

In addition to the above differences, other structures of the semiconductor structure 4 according to the fourth embodiment can refer to the corresponding structures of the semiconductor structures 1, 2 and 3 corresponding to the first to third embodiments.

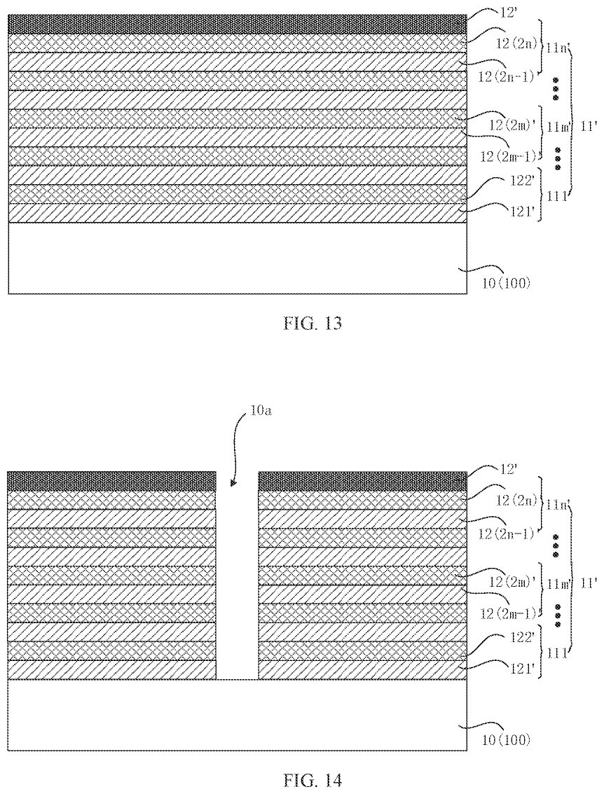

FIG. 13 and FIG. 14 are schematic diagrams of intermediate structures corresponding to a manufacturing method of the semiconductor structure according to the fourth embodiment of the present disclosure.

Accordingly, the manufacturing method of semiconductor structure 4 according to the fourth embodiment is different from the manufacturing methods of semiconductor structures 1, 2 and 3 according to the first to third embodiments in that:

referring to FIG. 13, in step S11, the first-type mask material layer 11′ formed on the base 10 includes a first mask material multilayer 111′, . . . , the N-th mask material multilayer 11n′, N is an integer greater than or equal to 2, where the M-th mask material multilayer 11m′ includes a (2M-1)-th mask material layer 12(2m-1)′ close to the base 10 and a (2M)-th mask material layer 12(2m)′ far from the base 10, M is any integer greater than or equal to 2 and less than or equal to N; and

the (2N)-th mask material layer 12(2n)′ in the N-th mask material multilayer 11n′, . . . , the (2M)-th mask material layer 12(2m)′ in the M-th mask material multilayer 11m′, . . . , and the second mask material layer 122′ in the first mask material multilayer 111′ are made of the same material, for example, silicon nitride. The (2N−1)-th mask material layer 12(2n-1)′ in the N-th mask material multilayer 11n′, . . . , the (2M-1)-th mask material layer 12(2m-1)′ in the M-th mask material multilayer 11m′, . . . , the first mask material layer 121′ in the first mask material multilayer 111′, and the second-type mask material layer 12′ are made of the same material, for example, silicon dioxide.

Referring to FIG. 14 and FIG. 11, in step S13, the (2N)-th mask material layer 12(2n)′ in the N-th mask material multilayer 11n′ is laterally etched through the opening 10a to form the (2N)-th window 12(2n)a, . . . , the (2M)-th mask material layer 12(2m)′ in the M-th mask material multilayer 11m′ is laterally etched through the opening 10a to form the (2M)-th window 12(2m)a, . . . , the second mask material layer 122′ in the first mask material multilayer 111′ is laterally etched through the opening 10a to form the second window 122a. A part of the opening 10a located in the (2N−1)-th mask material layer 12(2n-1)′ in the N-th mask material multilayer 11n′ forms the (2N−1)-th window 12(2n-1)a, . . . , a part of the opening 10a located in the (2M-1)-th mask material layer 12(2m-1)′ in the M-th mask material multilayer 11m′ forms the (2M-1)-th window 12(2m-1)a, . . . , a part of the opening 10a located at the first mask material layer 121′ in the first mask material multilayer 111′ forms a first window 122a.

The N-th mask material multilayer 11n′ forms the N-th mask multilayer 11n, the (2N)-th mask material layer 12(2n)′ forms the (2N)-th mask layer 12(2n), the (2N−1)-th mask material layer 12(2n-1)′ forms the (2N−1)-th mask layer 12(2n-1), . . . , the M-th mask material multilayer 11m′ forms the M-th mask multilayer 11m, and the (2M)-th mask material layer 12(2m)′ forms the (2M)-th mask layer 12(2m), the (2M-1)-th mask material layer 12(2m-1)′ forms the (2M-1)-th mask layer 12(2m-1), . . . , the first mask material multilayer 111′ forms the first mask multilayer 111, the second mask material layer 122′ forms the second mask layer 122, and the first mask material layer 121′ forms the first mask layer 121.

In the first-type mask layer 11, because all even-numbered mask layers have the same refractive index, all odd-numbered mask layers have the same refractive index, and the refractive index of even-numbered mask layers and the refractive index of odd-numbered mask layers are different, a Bragg reflector can be formed.

In other embodiments, the (2M-1)-th window 12(2m-1)a and the (2M)-th window 12(2m)a can also be realized by removing an occupying layer.

In addition to the above differences, other steps of the manufacturing method of the semiconductor structure 4 according to the fourth embodiment can refer to the corresponding steps of the manufacturing methods of the semiconductor structures 1, 2 and 3 according to the first to third embodiments.

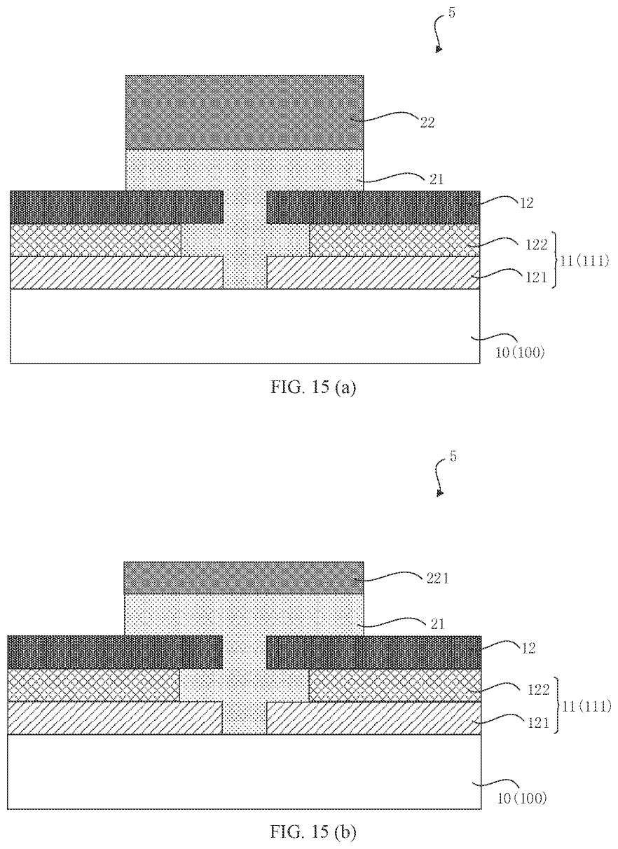

FIG. 15(a) and FIG. 15(b) are cross-sectional structure diagrams of two semiconductor structures according to a fifth embodiment of the present disclosure.

Referring to FIG. 15(a), a semiconductor structure 5 according to the fifth embodiment is different from the semiconductor structures 1, 2, 3 and 4 according to the first to fourth embodiments in that the semiconductor structure 5 further includes a light-emitting structure 22 located on a side of the epitaxial layer 21 far from the base 10.

The light-emitting structure 22 may include a first semiconductor layer, a second semiconductor layer, and an active layer between the first semiconductor layer and the second semiconductor layer, the conductivity type of the first semiconductor layer is opposite to the conductivity type of the second semiconductor layer.

The decrease of dislocation density of the epitaxial layer 21 can improve the crystal quality of the light-emitting structure 22, thus improving the light-emitting efficiency.

Accordingly, a manufacturing method of the semiconductor structure 5 in FIG. 15(a) is different from the manufacturing methods of the semiconductor structures 1, 2, 3 and 4 according to the first to fourth embodiments in that after step S2, the epitaxial growth is continued to form the light-emitting structure 22.

Referring to FIG. 15(b), a semiconductor structure 5 according to the fifth embodiment is different from the semiconductor structures 1, 2, 3 and 4 according to the first to fourth embodiments in that the semiconductor structure 5 further includes a light-emitting structure 22, and the light-emitting structure 22 includes an active layer 221 located on a side of the epitaxial layer 21 far from the base 10. It should be noted that the epitaxial layer 21 can be configured as the first semiconductor layer of the light-emitting structure 22. Accordingly, a manufacturing method of the semiconductor structure 5 in FIG. 15(b) is different from the manufacturing methods of semiconductor structures 1, 2, 3 and 4 according to the first to fourth embodiments in that in step S2, when the epitaxial layer 21 is formed during the whole or the end of the epitaxially growing process, N-type elements or P-type elements are doped; and after step S2, the epitaxial growth is continued to form the active layer 221 and the second semiconductor layer of the light-emitting structure 22.

In addition to the above differences, other structures and process steps of the semiconductor structure 5 according to the fifth embodiment can refer to the corresponding structures and process steps of the semiconductor structures 1, 2, 3 and 4 corresponding to the first to fourth embodiments.

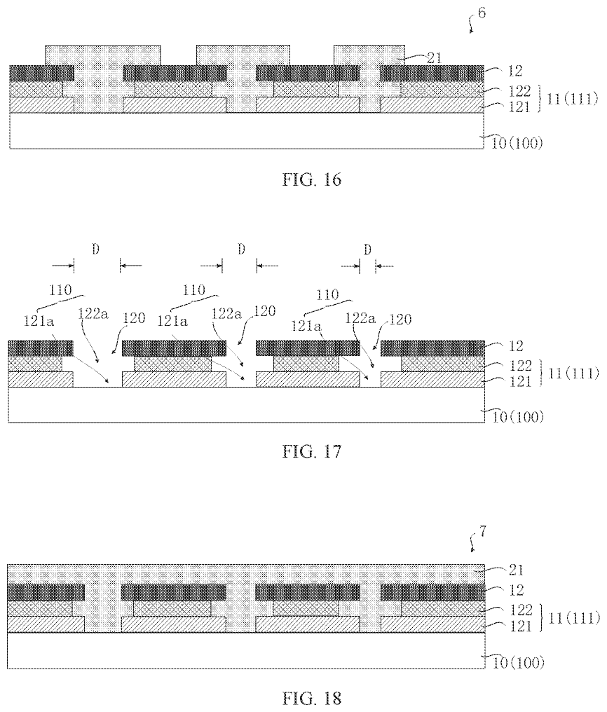

FIG. 16 is a cross-sectional structure diagram of a semiconductor structure according to a sixth embodiment of the present disclosure. FIG. 17 is a cross-sectional structure diagram of a base, a first-type mask layer and a second-type mask layer in FIG. 16.

Referring to FIG. 16 and FIG. 17, a semiconductor structure 6 and a manufacturing method thereof according to the sixth embodiment is different from the semiconductor structures 1, 2, 3, 4, 5 and manufacturing methods thereof according to the first to fifth embodiments in that a plurality of first-type windows 110 and a plurality of second-type windows 120 are provided. The combination of the plurality of the first-type windows 110 and the plurality of the second-type windows 120 can simultaneously and efficiently reduce the dislocation density in the plane where the base 10 is located.

Adjacent multiple second-type windows 120 may constitute a group, and an area of a cross-section of each second-type window 120 in the same group is different, or a spacing between each pairs of adjacent second-type windows 120 in the same group is different.

The smaller an area D of a cross-section of the second-type window 120, the smaller the proportion of the cross-section of the second-type window 120 in the unit area, that is, the smaller the proportion of the hole of the second-type window 120. The unit area refers to a unit area on the plane where the base 10 is located. Optionally, when a base material of the active layer 221 is GaN, the smaller the proportion of the hole of the second-type window 120 is, the faster the growth rate of the base material GaN of the active layer 221 in the second-type window 120. The doping of In element has better selectivity, such that the doping rate of In element is greater than the doping rate of Ga element. Therefore, the smaller the proportion of the hole of the second-type window 120, the higher the component content of In element in the active layer 221 InGaN, and the longer the wavelength of the emitted light from the light-emitting structure 22. The larger an area D of a cross-section of the second-type window 120, the lower the component content of In element in the InGaN active layer 221, and the shorter the wavelength of the emitted light from the light-emitting structure 22. It should be noted that the area D of the cross-section shown in FIG. 17 is only used to illustrate the size of the cross-section of the second-type window 120.

The larger the spacing between adjacent second-type windows 120, the smaller the proportion of the cross-section of the second-type window 120 in the unit area, that is, the smaller the proportion of hole of the second-type window 120, the higher the component content of In element in the active layer 221 InGaN, and the longer the wavelength of the emitted light from the light-emitting structure 22. The smaller the spacing between the adjacent second-type windows 120, the lower the component content of In element in the active layer 221 InGaN, and the shorter the wavelength of the emitted light from the light-emitting structure 22.

In addition to the above differences, other structures and process steps of the semiconductor structure 6 according to the sixth embodiment can refer to the corresponding structures and process steps of the semiconductor structures 1, 2, 3, 4 and 5 corresponding to the first to fifth embodiments.

FIG. 18 is a cross-sectional structure diagram of a semiconductor structure according to a seventh embodiment of the present disclosure. FIG. 19 is a schematic top view of a base, a first-type mask layer and a second-type mask layer in FIG. 18.

Referring to FIG. 18 and FIG. 19, a semiconductor structure 7 according to the seventh embodiment is different from the semiconductor structures 1, 2, 3, 4 and 5 according to the first to fifth embodiments in that a plurality of first-type windows 110 and a plurality of second-type windows 120 are provided, and epitaxial layers 21 corresponding to the plurality of the first-type windows 110 and the plurality of the second-type windows 120 coalesce into a plane.

Referring to FIG. 19, in this embodiment, the cross-section of each second-type window 120 is hexagonal, where the cross-section refers to a cross-section parallel to the plane of the base 10. In other embodiments, the cross-section of the second-type window 120 can also be rectangular, triangular, circular and other shapes.

GaN-based devices, such as LD, LED or HEMT devices, can be formed on the epitaxial layer 21.

In addition to the above differences, other structures and process steps of the semiconductor structure 7 according to the seventh embodiment can refer to the corresponding structures and process steps of the semiconductor structures 1, 2, 3, 4 and 5 corresponding to the first to fifth embodiments.

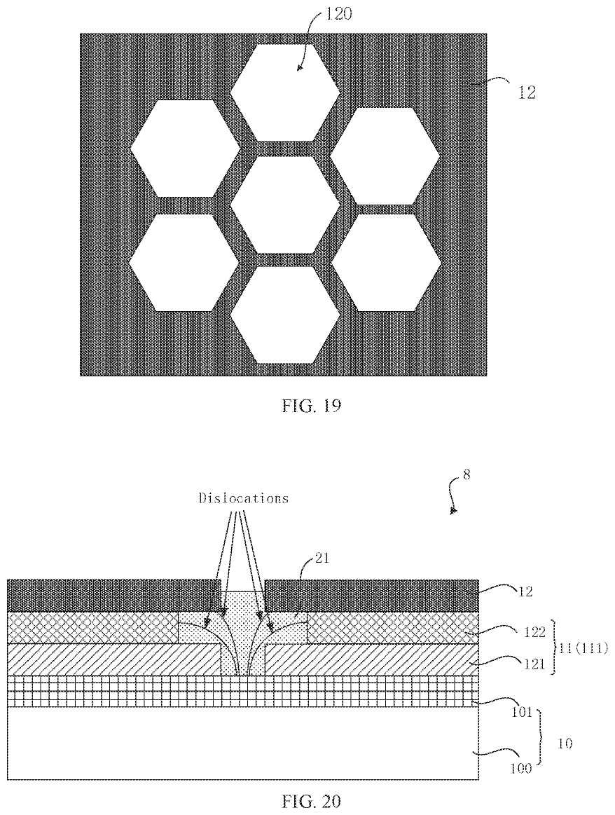

FIG. 20 is a cross-sectional structure diagram of a semiconductor structure according to a eighth embodiment of the present disclosure.

Referring to FIG. 20, a semiconductor structure 8 and a manufacturing method thereof according to the eighth embodiment is different from the semiconductor structures 1, 2, 3, 4, 5, 6, 7 and manufacturing methods thereof according to the first to seventh embodiments in that the base 10 includes a semiconductor substrate 100 and a transition layer 101 located on the semiconductor substrate 100.

The transition layer 101 and the epitaxial layer 21 can be the same material or different materials.

The material of the transition layer 101 include GaN, for example. Compared with the embodiment where the transition layer 101 is omitted, and the epitaxial layer 21 whose material includes AlGaN, InGaN or AlInGaN is epitaxially grown directly on the sapphire or monocrystalline silicon semiconductor substrate 100, in this embodiment, the dislocation density of the epitaxial layer 21 can be further reduced.

In addition to the above differences, other structures and process steps of the semiconductor structure 8 according to the eighth embodiment can refer to the corresponding structures and process steps of the semiconductor structures 1, 2, 3, 4, 5, 6 and 7 corresponding to the first to seventh embodiments.

Although the present disclosure is disclosed as above, the present disclosure is not limited thereto. Any person skilled in the art can make various changes and modifications without departing from the spirit and scope of the present disclosure, and therefore the scope of protection of the present disclosure shall be subject to the scope defined by the claims.

What is claimed is:

1. A semiconductor structure, comprising:
a base;
a first-type mask layer on the base, wherein the first-type mask layer comprises a first-type window, the first-type mask layer comprises a first mask multilayer, the first mask multilayer comprises a first mask layer close to the base and a second mask layer far from the base, the first mask layer comprises a first window, the second mask layer comprises a second window, the second window connects to the first window, the first window and the second window constitute the first-type window, and an area of a cross-section of the second window is larger than an area of a cross-section of the first window, wherein the cross-section refers to a section parallel to a plane of the base; and
a second-type mask layer on a side of the first-type mask layer far from the base, wherein the second-type mask layer comprises a second-type window, the second-type window connects to the first-type window, and an area of a cross-section of the second-type window is smaller than the area of the cross-section of the second window.

2. The semiconductor structure according to claim 1, wherein a material of the first mask layer is the same as a material of the second-type mask layer and is different from a material of the second mask layer.

3. The semiconductor structure according to claim 1, further comprising:
a third-type mask layer between the first-type mask layer and the base, wherein the third-type mask layer comprises a third-type window that exposes the base, the third-type window connects to the first-type window, and an area of a cross-section of the third-type window is larger than the area of the cross-section of the first window.

4. The semiconductor structure according to claim 1, wherein the first-type mask layer further comprises a second mask multilayer, . . . , an N-th mask multilayer, N is an integer greater than or equal to 2, a M-th mask multilayer comprises a (2M-1)-th mask layer close to the base and a (2M)-th mask layer far from the base, M is an integer greater than or equal to 2 and less than or equal to N, the (2M-1)-th mask layer comprises a (2M-1)-th window, the (2M)-th mask layer comprises a (2M)-th window, the (2M)-th window connects to the (2M-1)-th window, the (2M)-th window and the (2M-1)-th window constitute at least part of the first-type window, an area of a cross-section of the (2M)-th window is larger than an area of a cross-section of the (2M-1)-th window, and the area of the cross-section of the second-type window is smaller than an area of a cross-section of a (2N)-th window.

5. The semiconductor structure according to claim 4, wherein the area of the cross-section of the (2M-1)-th window is smaller than an area of a cross-section of a (2M-2)-th window.

6. The semiconductor structure according to claim 4, wherein in the first-type mask layer, all even-numbered mask layers have the same refractive index, all odd-numbered mask layers have the same refractive index, and the refractive index of the even-numbered mask layers is different from the refractive index of the odd-numbered mask layers to form a Bragg reflector.

7. The semiconductor structure according to claim 1, further comprising:
an epitaxial layer in the first-type window and the second-type window.

8. The semiconductor structure according to claim 7, further comprising:
a light-emitting structure on a side of the epitaxial layer far from the base.

9. The semiconductor structure according to claim 8, wherein the light-emitting structure comprises an active layer on a side of the epitaxial layer far from the base.

10. The semiconductor structure according to claim 7, wherein the semiconductor structure comprises a plurality of the first-type windows and a plurality of the second-type windows, adjacent multiple second-type windows constitute a group, and an area of a cross-section of each second-type window in the same group is different, or a spacing between each pairs of adjacent second-type windows in the same group is different.

11. The semiconductor structure according to claim 7, wherein the semiconductor structure comprises a plurality of the first-type windows and a plurality of the second-type windows, and epitaxial layers corresponding to the plurality of the first-type windows and the plurality of the second-type windows coalesce into a plane.

12. A manufacturing method of a semiconductor structure, comprising:
providing a base; and
sequentially forming a first-type mask layer and a second-type mask layer on the base; wherein the first-type mask layer comprises a first-type window, the first-type mask layer comprises a first mask multilayer, the first mask multilayer comprises a first mask layer close to the base and a second mask layer far from the base, the first mask layer comprises a first window, the second mask layer comprises a second window, the second window connects to the first window, the first window and the second window constitute the first-type window, and an area of a cross-section of the second window is larger than an area of a cross-section of the first window, wherein the cross-section refers to a section parallel to a plane of the base, and the second-type mask layer comprises a second-type window, the second-type window connects to the first-type window, and an area of a cross-section of the second-type window is smaller than the area of the cross-section of the second window.

13. The manufacturing method according to claim 12, further comprising:
performing an epitaxial growth process on the base, by using the first-type mask layer and the second-type mask layer as masks, to form an epitaxial layer, wherein the epitaxial layer fills up the first-type window and the second-type window.

14. The manufacturing method according to claim 12, wherein a material of the first mask layer is the same as a material of the second-type mask layer and is different from a material of the second mask layer; and
sequentially forming the first-type mask layer and the second-type mask layer on the base comprises:
sequentially forming a first-type mask material layer and a second-type mask material layer on the base, wherein the first-type mask material layer comprises a first mask material multilayer, and the first mask material multilayer comprises a first mask material layer close to the base and a second mask material layer far from the base;
etching the second-type mask material layer and the first-type mask material layer to form an opening that exposes the base; and
laterally etching the second mask material layer through the opening to form the second window, wherein a part of the opening located in the first mask material layer forms the first window, and a part of the opening located in the second-type mask material layer forms the second-type window.

15. The manufacturing method according to claim 12, wherein before forming the first-type mask layer on the base, the manufacturing method further comprises:
forming a third-type mask layer on the base, wherein the third-type mask layer comprises a third-type window that exposes the base, the third-type window connects to the first-type window, and an area of a cross-section of the third-type window is larger than the area of the cross-section of the first window.

16. The manufacturing method according to claim 15, wherein a material of the first mask layer is the same as a material of the second-type mask layer, a material of the second mask layer is the same as a material of the third-type mask layer and is different from a material of the first mask layer; and
sequentially forming the first-type mask layer and the second-type mask layer on the base comprises:
sequentially forming a third-type mask material layer, a first-type mask material layer and a second-type mask material layer on the base, wherein the first-type mask material layer comprises a first mask material layer close to the base and a second mask material layer far from the base;
etching the second-type mask material layer, the first-type mask material layer and the third-type mask material layer to form an opening that exposes the base; and
laterally etching the second mask material layer through the opening to form the second window, and laterally etching the third-type mask material layer through the opening to form the third-type window, wherein a part of the opening located in the first mask material layer forms the first window, and a part of the opening located in the second-type mask material layer forms the second-type window.
